(19) United States
(12) Patent Application Publication
(10) Pub. No.: US 2025/0022807 A1
(43) Pub. Date: Jan. 16, 2025

(54) SEMICONDUCTOR DEVICE AND MANUFACTURING METHOD OF THE SEMICONDUCTOR DEVICE

(71) Applicant: SK hynix Inc., Gyeonggi-do (KR)

(72) Inventors: Joon Seuk LEE, Gyeonggi-do (KR); Woo Sung MOON, Gyeonggi-do (KR)

(21) Appl. No.: 18/488,036

(22) Filed: Oct. 17, 2023

(30) Foreign Application Priority Data
Jul. 12, 2023 (KR) 10-2023-0090357

(51) Int. Cl. H01L 23/544; H01L 23/00; H10B 43/27

(52) U.S. Cl. CPC H01L 23/544; H01L 23/564; H10B 43/27; H01L 2223/54426; H01L 2223/5446

(57) ABSTRACT

A semiconductor device may include a lower structure including a chip region and a scribe lane region surrounding the chip region, a first alignment pattern including first alignment keys extending parallel to each other along a first direction on the scribe lane region, and a support pattern including first sub-support patterns arranged along a second direction intersecting the first direction between the first alignment keys.

### CROSS-REFERENCE TO RELATED APPLICATION

The present application claims priority under 35 U.S.C. § 119 (a) to Korean patent application number 10-2023-0090357 filed on Jul. 12, 2023, the entire disclosure of which is incorporated by reference herein.

### BACKGROUND

### 1. Field of Invention

Embodiments of the present disclosure generally relate to a semiconductor device and a manufacturing method of the semiconductor device, and more particularly, to a semiconductor device including an alignment pattern on a scribe lane and a manufacturing method of the semiconductor device.

### 2. Description of Related Art

A plurality of semiconductor chip regions may be formed on a semiconductor substrate through a semiconductor integration process. The plurality of semiconductor chip regions may be separated from each other by using a scribe lane region as a boundary. The plurality of semiconductor chip regions may be separated from each other through a cutting process on the semiconductor substrate, to be manufactured as a plurality of semiconductor chips.

Meanwhile, when a lithography operation of the semiconductor integration process is performed, an alignment pattern may be used to align a photomask at a predetermined position of the semiconductor substrate. The alignment pattern is located on the scribe lane region, so that the degree of integration of the semiconductor chip is not deteriorated.

### SUMMARY

Various embodiments of the present disclosure provide a semiconductor device and a manufacturing method of the semiconductor device, in which the structural stability of a region in which an alignment pattern is formed can be improved, thereby reducing occurrence of defects.

In accordance with an embodiment of the present disclosure, there is provided a semiconductor device including: a lower structure including a chip region and a scribe lane region surrounding the chip region; a first alignment pattern including first alignment keys extending parallel to each other along a first direction on the scribe lane region; and a support pattern including first sub-support patterns arranged along a second direction intersecting the first direction between the first alignment keys.

In accordance with another embodiment of the present disclosure, there is provided a method of manufacturing a semiconductor device, the method including: forming a stack structure by alternately stacking first material layers and second material layers on a lower structure including a chip region and a scribe lane region surrounding the chip region; forming sub-support patterns penetrating the stack structure of the scribe lane region, the sub-support patterns being arranged along a first direction; forming trenches penetrating the stack structure of the scribe lane region, the trenches extending parallel to each other along a second direction intersecting the first direction; forming recesses by removing the first material layers exposed through the trenches; forming third material layers in the recesses through the trenches; and forming an alignment pattern by filling a fourth material layer in the trenches.

### BRIEF DESCRIPTION OF THE DRAWINGS

Various embodiments of the present disclosure will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is view illustrating a structure of a semiconductor device in accordance with an embodiment of the present disclosure.

FIGS. 2A and 2B are views illustrating a structure of the semiconductor device in accordance with an embodiment of the present disclosure.

FIGS. 3A to 3H are views illustrating a manufacturing method of the semiconductor device in accordance with an embodiment of the present disclosure.

FIGS. 4 to 7 are views illustrating structures of the semiconductor device in accordance with various embodiments of the present disclosure.

FIG. 8 is a diagram illustrating a memory card system to which the memory device of the present disclosure is applied.

FIG. 9 is a diagram illustrating a Solid State Drive (SSD) system to which the memory device of the present disclosure is applied.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, embodiments of the present disclosure will be described in detail with reference to the accompanying drawings in order for those skilled in the art to be able to readily implement the technical spirit of the present disclosure.

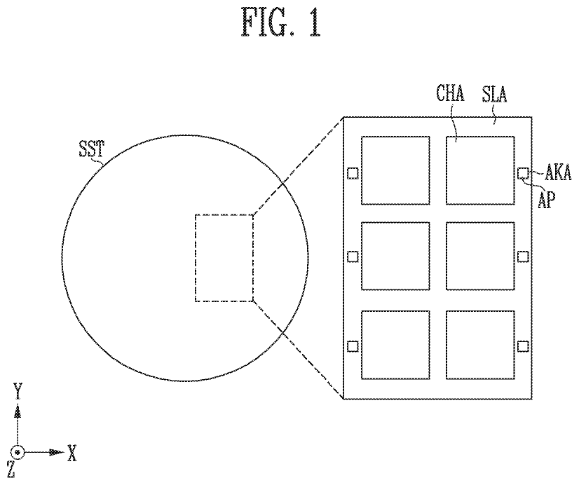

FIG. 1 is view illustrating a structure of a semiconductor device in accordance with an embodiment of the present disclosure.

Referring to FIG. 1, the semiconductor device may include a substrate SST. The substrate SST may include chip regions CHA and a scribe lane region SLA. For example, the substrate SST may include a plurality of chip regions CHA spaced apart from each other at a regular interval and the scribe lane region SLA surrounding the chip regions CHA. The substrate SST may be a semiconductor substrate such as a silicon wafer, a silicon-germanium (“SiGe”) wafer, or an SOI (silicon on insulator) wafer. In an embodiment of the present disclosure, the substrate SST may be designated as a lower structure.

The chip regions CHA may be regions in which semiconductor chips are respectively formed. The chip regions CHA may be arranged in an X direction and a Y direction, in multiple columns and multiple rows The semiconductor chips may be individually formed through a semiconductor integration process performed on the chip regions CHA. The semiconductor chips respectively formed in the chip regions CHA may be substantially the same. After the semiconductor integration process on the substrate SST is completed, the substrate SST is separated for each of the chip regions CHA, so that each of the chip regions CHA can be separated in a semiconductor chip form.

The scribe lane region SLA may be located at the outside of the chip regions CHA. The scribe lane region SLA may be located between the chip regions CHA. After the semiconductor integration process is completed, the scribe lane region SLA may be cut in a dicing process for separating the semiconductor chips from each other. The substrate SST is cut along the scribe lane region SLA, so that each of the chip regions CHA can be separated. A process such as a sawing process using a blade, a laser process using laser, or a stealth dicing process may be used as a process for cutting the substrate SST. A chip guard for protecting the chip regions CHA, an electrical test pattern, a process monitoring pattern, and an alignment pattern AP may be disposed in the scribe lane region SLA.

Referring to FIG. 1, an alignment key region AKA may be defined in one region of the scribe lane region SLA. The alignment key region AKA may be a region in which alignment patterns AP are formed. The alignment patterns AP may be pattern structures formed on the substrate SST for the purpose of alignment between a photomask and the substrate SST in a lithography operation of the semiconductor integration process. For example, the alignment patterns AP may be used when one or more of cell plugs, contact plugs, bit lines, and slit insulating layers of a semiconductor chip are formed. However, the present disclosure is not limited thereto, and the alignment patterns AP may be formed to form various structures in the semiconductor chip.

In FIG. 1, for convenience of description, six chip regions CHA are illustrated arranged in two columns and three rows. However, the scope of the present disclosure is not limited thereto. For example, the substrate SST may include various numbers of chip regions CHA, i.e., seven or more chip regions CHA. Also, in FIG. 1, it is illustrated that six alignment key regions AKA are included in the scribe lane region SLA. However, the scope of the present disclosure is not limited thereto. The positions and number of alignment key regions AKA included in the scribe lane region SLA may be variously modified. For example, the alignment key region AKA may be formed even at any position of the periphery of the chip region CHA. In another example, at least two alignment key regions AKA may be located adjacent to a chip region CHA. Also, in FIG. 1 each chip region CHA has a square shape, however, the scope of the present disclosure is not limited thereto.

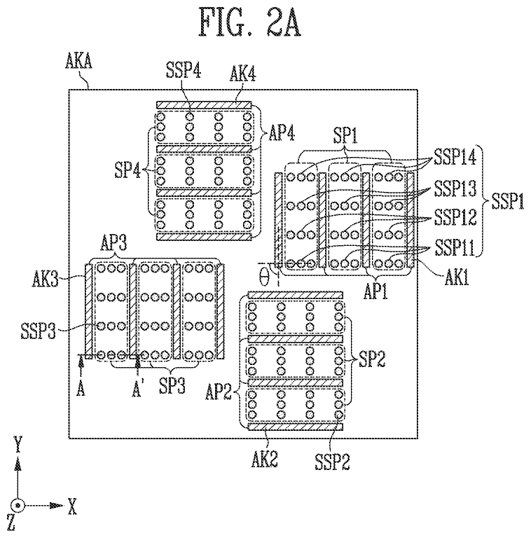

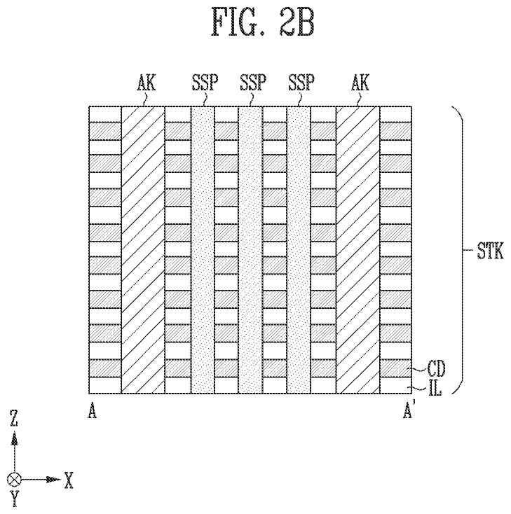

FIGS. 2A and 2B are views illustrating a structure of the semiconductor device in accordance with an embodiment of the present disclosure. FIG. 2A is a plan view illustrating a layout of alignment patterns AP formed in an alignment key region AKA. FIG. 2B is a sectional view taken along line A-A′ shown in FIG. 2A.

Referring to FIG. 2A, alignment patterns AP1, AP2, AP3, and AP4 and support patterns SP1, SP2, SP3, and SP4 may be located in the alignment key region AKA. The alignment pattern AP shown in FIG. 1 may include the alignment patterns AP1, AP2, AP3, and AP4 shown in FIG. 2A. The alignment patterns AP1, AP2, AP3, and AP4 may be Vernier key patterns. The Vernier key patterns are key patterns used to measure the alignment between upper and lower layers during the lithography operation. The alignment patterns AP1, AP2, AP3, and AP4 and the support patterns SP1, SP2, SP3, and SP4 may be formed in the scribe lane region SLA shown in FIG. 1.

The alignment patterns AP1, AP2, AP3, and AP4 may be disposed in a pinwheel shape such that each of the alignment patterns AP1, AP2, AP3, and AP4 faces in the X direction or the Y direction. Four alignment patterns AP1, AP2, AP3, and AP4 may be sequentially arranged clockwise. For example, a first alignment pattern AP1 may be disposed at a right upper position, a second alignment pattern AP2 may be disposed at a right lower position, a third alignment pattern AP3 may be disposed at a left lower position, and a fourth alignment pattern may be disposed at a left upper position. Each alignment pattern may have a rectangular overall shape and may be oriented at a 90 degree angle with its adjacent alignment patterns. For example, the first alignment pattern AP1 may be disposed at a right upper position and may be oriented in the X direction, the second alignment pattern AP2 may be disposed at a right lower position and may be oriented in the Y direction, the third alignment pattern AP3 may be disposed at a left lower position and may be oriented in the X direction, and the fourth alignment pattern may be disposed at a left upper position and may be oriented in the Y direction. However, this is merely illustrative, and the scope of the present disclosure is not limited thereto. For example, the alignment patterns AP1, AP2, AP3, and AP4 may be disposed in a chessboard shape instead of the pinwheel shape. When the alignment patterns AP1, AP2, AP3, and AP4 are disposed in the chessboard shape, the second alignment pattern AP2 may be disposed below the first alignment pattern AP1, the third alignment pattern AP3 may be disposed in a left diagonal direction of the first alignment pattern AP1, and the fourth alignment pattern AP4 may be disposed at a left side of the first alignment pattern AP1. Alternatively, at least one of the alignment patterns AP1, AP2, AP3, and AP4 may be omitted such that two or three alignment patterns are formed in the alignment key region AKA. Alternatively, the alignment patterns AP1, AP2, AP3, and AP4 may be arranged in a shape obtained by laterally or vertically inverting the shape shown in FIG. 2A.

The alignment patterns AP1, AP2, AP3, and AP4 may include alignment keys AK1, AK2, AK3, and AK4 arranged in parallel to each other, respectively. Each of the alignment keys AK1, AK2, AK3, and AK4 may extend parallel to each other in a corresponding alignment pattern among the alignment patterns AP1, AP2, AP3, and AP4. For example, the first alignment pattern AP1 may include first alignment keys AK1 extending parallel to each other along the Y direction. In addition, the second alignment pattern AP2 may include second alignment keys AK2 extending parallel to each other along the X direction. In addition, the third alignment pattern AP3 may include third alignment keys AK3 extending parallel to each other along the Y direction. In addition, the fourth alignment pattern AP4 may include fourth alignment keys AK4 extending parallel to each other along the X direction. The number of alignment keys AK1, AK2, AK3 or AK4 included in each of the alignment patterns AP1, AP2, AP3, and AP4 and the distance between the alignment keys AK1, AK2, AK3 or AK4 included in each of the alignment patterns AP1, AP2, AP3, and AP4 are not limited to those shown in FIG. 2A.

Each of the alignment keys AK1, AK2, AK3 or AK4 may have a rectangular section. A length of the section of each of the alignment keys AK1, AK2, AK3 or AK4 in one direction may be longer than a length of the section of each of the alignment keys AK1, AK2, AK3 or AK4 in the other direction. For example, a section of each of the first alignment keys AK1 may be provided in a rectangular shape having long sides in the Y direction and short sides in the X direction. In addition, a section of each of the second alignment keys AK2 may be provided in a rectangular shape having long sides in the X direction and short sides in the Y direction. In addition, a section of each of the third alignment keys AK3 may be provided in a rectangular shape having long sides in the Y direction and short sides in the X direction. In addition, a section of each of the fourth alignment keys AK4 may be provided in a rectangular shape having long sides in the X direction and short sides in the Y direction. In FIG. 2A, it is illustrated that each of the alignment keys AK1, AK2, AK3 or AK4 has a rectangular shape. However, the scope of the present disclosure is not limited thereto. For example, each of the alignment keys AK1, AK2, AK3 or AK4 may have sections with various shapes such as an ellipse and a rectangular having round corners.

The support patterns SP1, SP2, SP3, and SP4 may include sub-support patterns SSP1, SSP2, SSP3, and SSP4 located between the alignment keys AK1, AK2, AK3, and AK4. For example, a first support pattern SP1 may include first sub-support patterns SSP1 (e.g., SSP11, SSP12, SSP13 or SSP14) arranged along the X direction between the first alignment keys AK1. In addition, a second support pattern SP2 may include second sub-support patterns SSP2 arranged along the Y direction between the second alignment keys AK2. A third support pattern SP3 may include third sub-support patterns SSP3 arranged along the X direction between the third alignment keys AK3. In addition, a fourth support pattern SP4 may include fourth sub-support patterns SSP4 arranged along the Y direction between the fourth alignment keys AK4. In FIG. 2A, the first support pattern SP1 is mainly described. However, this is for convenience of description, and descriptions of the first support pattern SP1 may be applied to the second to fourth support patterns SP2 to SP4, except limitation to the X or Y direction.

The first support pattern SP1 may include first sub-support patterns SSP1 located between the first alignment keys AK1. The first sub-support patterns SSP1 may be arranged along the X direction and the Y direction. The first sub-support patterns SSP1 may be divided according to directions in which the first sub-support patterns SSP1 are arranged. For example, the first sub-support patterns SSP1 may be divided into eleventh sub-support patterns SSP11, twelfth sub-support patterns SSP12 located in the Y direction with respect to the eleventh sub-support patterns SSP11, thirteenth sub-support patterns SSP13 located in the Y direction with respect to the twelfth sub-support patterns SSP12, and fourteenth sub-support patterns SSP14 located in the Y direction with respect to the thirteenth sub-support patterns SSP13. The number of first sub-support patterns SSP1 arranged in the Y direction is not limited to that shown in FIG. 2A.

The eleventh sub-support patterns SSP11 may be located in parallel to each other along the X direction. The twelfth sub-support patterns SSP12 may be located in parallel to each other along the X direction. The thirteenth sub-support patterns SSP13 may be located in parallel to each other along the X direction. The fourteenth sub-support patterns SSP14 may be located in parallel to each other along the X direction. The number of each of the eleventh to fourteenth sub-support patterns SSP11 to SSP14 arranged in the X direction is not limited to that shown in FIG. 2A.

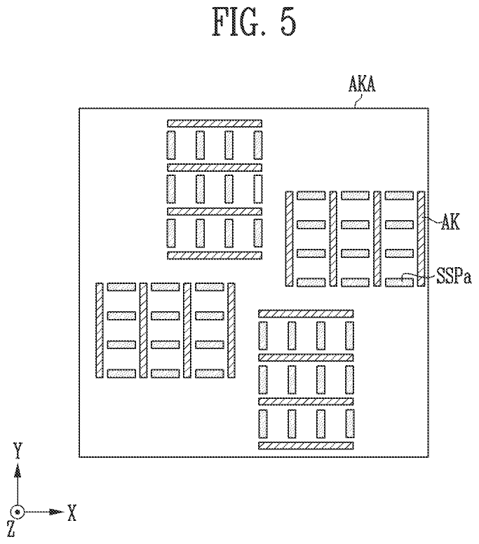

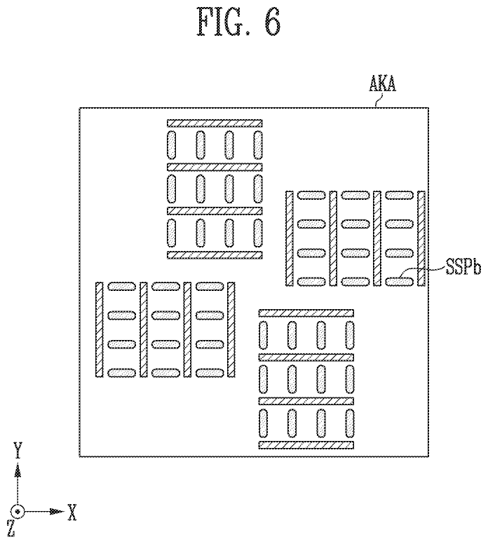

The first sub-support patterns SSP1 may be located between the first alignment keys AK1. In an embodiment, at least two eleventh sub-support patterns SSP11 (, SSP12, SSP13 or SSP14) may be located between two alignment keys adjacent to each other among the first alignment keys AK1. For example, three eleventh sub-support patterns SSP11 may be arranged in parallel to each other in the X direction between two alignment keys adjacent to each other among the first alignment keys AK1. However, this is merely illustrative. In another embodiment, only one eleventh sub-support pattern SSP11, only one twelfth sub-support pattern SSP12, only one thirteenth sub-support pattern SSP13, and only one fourteenth sub-support pattern SSP14 may be located between two alignment keys adjacent to each other among the first alignment keys AK1. This will be described later with reference to FIGS. 5 and 6.

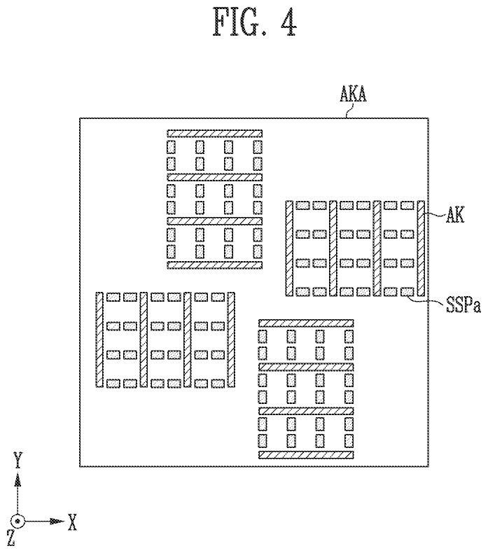

In an embodiment, a section of each of the first sub-support patterns SSP1 may have a circular shape. For example, the section of each of the first sub-support patterns SSP1 may be a circle having the same length in the X direction and the Y direction. In another embodiment, the section of each of the first sub-support patterns SSP1 may be a rectangular, a quadrangle having round corners, or an ellipse. Various embodiments of the section of each of the first sub-support patterns SSP1 will be described later with reference to FIGS. 4 to 6.

Each of the first sub-support patterns SSP1 and each of the first alignment keys AK1 may be spaced apart from each other. For example, the first sub-support patterns SSP1 may be spaced apart from each of the first alignment keys AK1. Also, the first sub-support patterns SSP1 may be located to be spaced apart from each other.

Referring to FIG. 2A, the direction (e.g., the Y direction) in which the first alignment keys AK1 extend and the direction (e.g., the X direction) in which the eleventh sub-support patterns SSP11 (, SSP12, SSP13 or SSP14) are arranged may be substantially perpendicular to each other. That is, an angle θ formed by the direction in which the first alignment keys AK1 extend and the direction in which each of the eleventh to fourteenth sub-support patterns SSP11 to SSP14 are arranged may be 90 degrees. In accordance with embodiments of the present disclosure, since the eleventh sub-support patterns SP11 are arranged in the direction (e.g., the Y direction) substantially perpendicular to the direction (e.g., the X direction) in which the first alignment keys AK1 are arranged, the support patterns SP1, SP2, SP3, and SP4 may have no influence during an alignment operation performed using the alignment patterns AP1, AP2, AP3, and AP4. That is, although the support patterns SP1, SP2, SP3, and SP4 are formed, the support patterns SP1, SP2, SP3, and SP4 have no influence when an overlay is measured through the alignment patterns AP1, AP2, AP3, and AP4. Thus, an operation of adjusting alignment between the substrate SST and the photomask, using the alignment patterns AP1, AP2, AP3, and AP4, is possible.

FIG. 2B is a sectional view corresponding to a section taken along the line A-A′ shown in FIG. 2A. Although FIG. 2B illustrates a section of the third alignment keys AK3 and the third sub-support patterns SSP3, sectional structures of the first to fourth alignment patterns AP1 to AP4 are substantially the same, and sectional structures of the first to fourth support patterns SP1 to SP4 are substantially the same. Hence, in FIG. 2B, alignment keys or sub-support patterns will be described without distinguishing the alignment keys or the sub-support patterns from each other. Therefore, descriptions of alignment keys AK and sub-support patterns SSP, which are illustrated in FIG. 2B, may be applied to the first to fourth alignment keys AK1 to AK4 and the first to fourth sub-support patterns SSP1 to SSP4.

Referring to FIG. 2B, a stack structure STK may be located on a substrate (not shown) or a lower structure (not shown) of the scribe lane region SLA. The stack structure STK may include conductive layers CD and interlayer insulating layers IL, which are alternately stacked. Referring to FIG. 2B together with FIG. 1, the stack structure STK may be formed on the scribe lane region SLA together with a stack structure formed on the chip region CHA. For example, materials stacked in the stack structure on the chip region CHA and materials (e.g., the conductive layers CD and the interlayer insulating layers IL) stacked in the stack structure STK on the scribe lane region SLA may be substantially the same.

Alignment keys AK may be located to be spaced apart from each other in the X direction. Each of the alignment keys AK may extend in the Y direction. The alignment keys AK may be formed in parallel to each other in the X direction. Also, each of the alignment keys AK may penetrate the stack structure STK in a Z direction. The alignment keys AK may be formed of an insulating material such as an oxide layer, but the present disclosure is not limited thereto.

Sub-support patterns SSP may be arranged along the X direction between the alignment keys AK. Also, each of the sub-support patterns SSP may extend in the Z direction to penetrate the stack structure STK. For example, each of the sub-support patterns SSP may have a circular pillar shape extending vertically from the substrate SST. Each of the sub-support patterns SSP may be made of a conductive material.

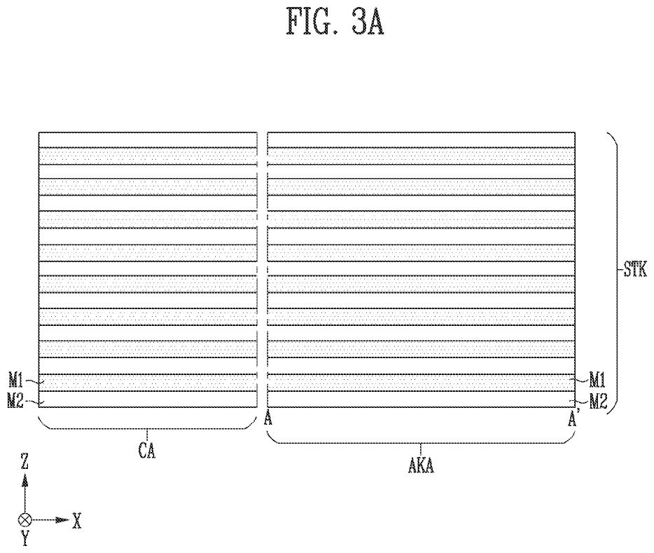

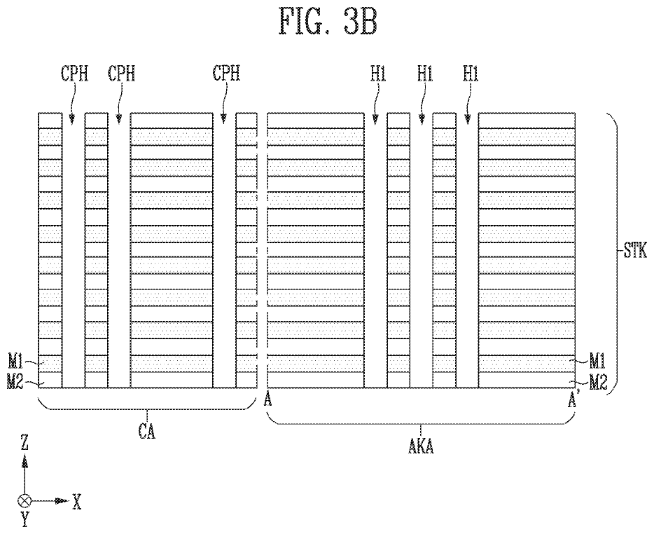

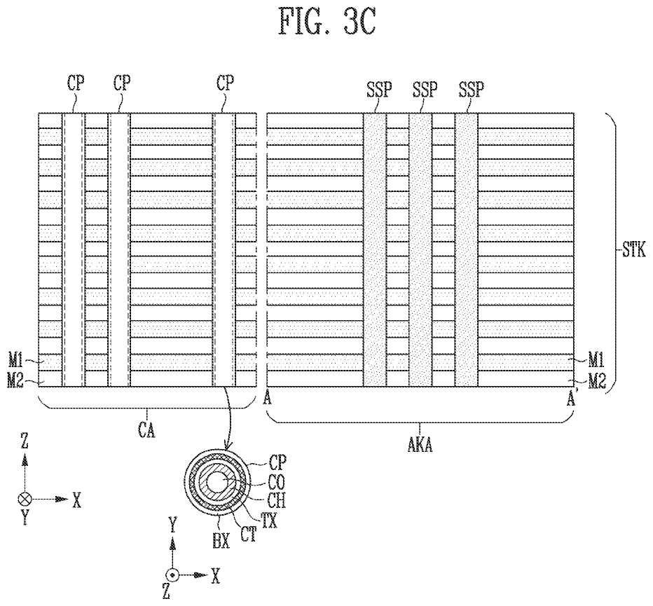

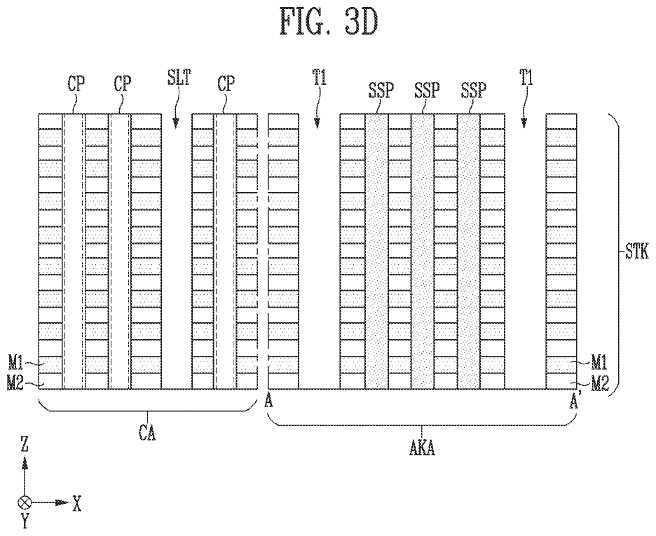

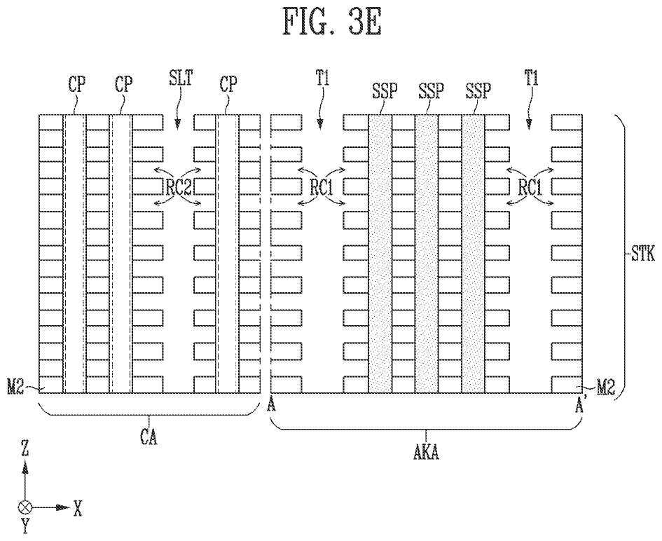

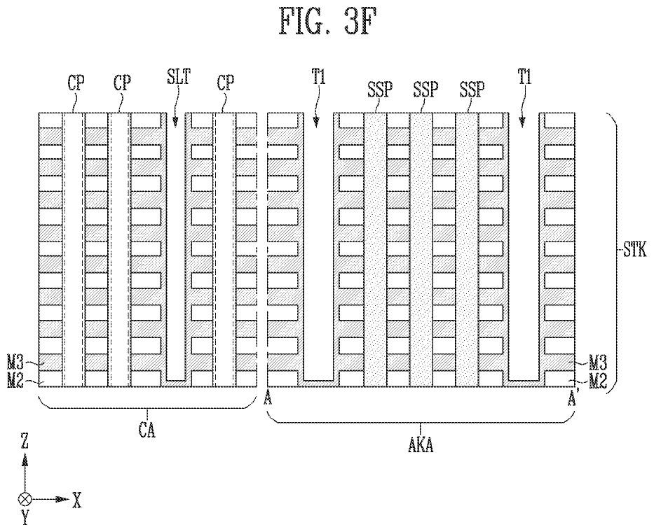

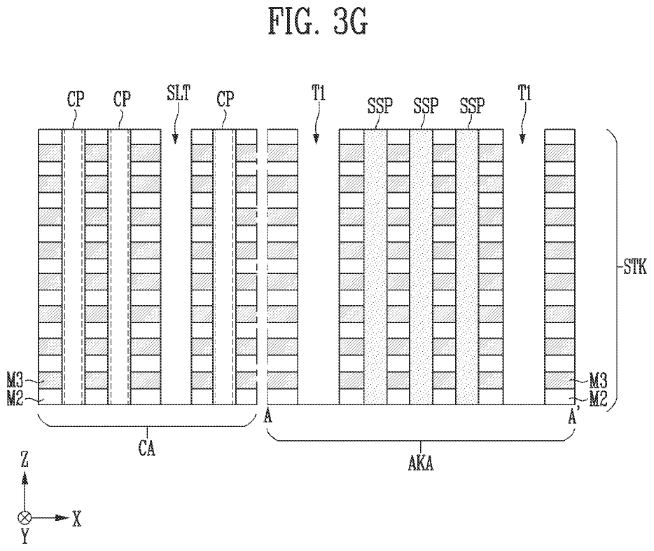

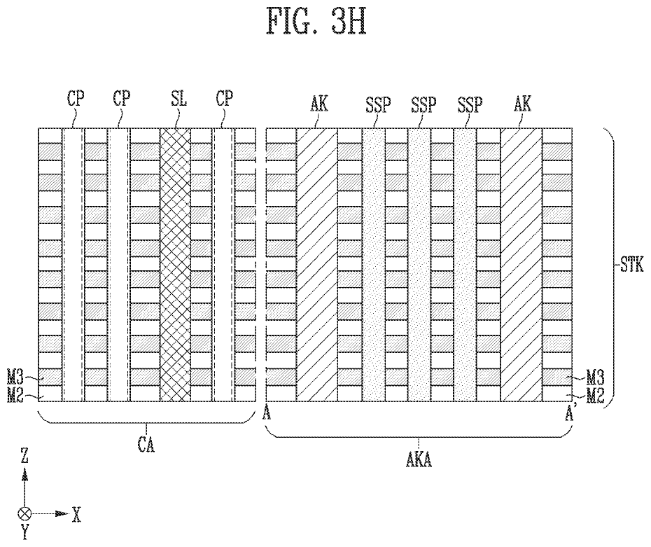

FIGS. 3A to 3H are views illustrating a manufacturing method of the semiconductor device in accordance with an embodiment of the present disclosure. Each of FIGS. 3A to 3H includes a sectional view taken along the line A-A′ shown in FIG. 2A and a sectional view of a cell array region CA as a portion of the chip region CHA.

Referring to FIG. 3A, first and second material layers M1 and M2 may be alternately stacked on the substrate SST. A stack structure STK may be formed on each of a cell array region CA included in the chip region CHA and an alignment key region AKA included in the scribe lane region SLA. The stack structures STK of the cell array region CA and a stack structure STK of the alignment key region AKA may be simultaneously formed. First and second material layers M1 and M2 on the cell array region CA may be formed of the same materials as first and second material layers M1 and M2 on the alignment key region AKA, respectively.

The first material layers M1 may be formed of a material which can be selectively removed in a subsequent process. Therefore, the first material layers M1 may be formed of a material having an etch selectivity different from an etch selectivity of the second material layers M2. For example, the first material layers M1 may be formed of a nitride layer. The second material layers M2 may be formed of an insulating material. For example, the second material layers M2 may be formed of an oxide layer (e.g., a silicon oxide layer). The second material layer M2 may be formed at each of a lowermost end and an uppermost end in the stack structure STK in which the first and second material layers M1 and M2 are stacked.

Referring to FIG. 3B, cell holes CPH penetrating the stack structure STK in the Z direction may be formed in the cell array region CA. Each of the cell holes CPH may penetrate the first material layers M1 and the second material layers M2. The cell holes CPH may be spaced apart from each other along the X direction. An anisotropic dry etching process may be performed to form the cell holes CPH at specified positions.

In addition, support holes H1 penetrating the stack structure STK in the Z direction may be formed in the alignment key region AKA. Each of the support holes H1 may penetrate the first material layers M1 and the second material layers M2. The support holes H1 may be arranged along the X direction. An anisotropic dry etching process may be performed to form the support holes H1 at specified positions.

Referring to FIG. 3C, cell plugs CP may be formed in the cell holes CPH formed in the cell array region CA. Each of the cell plugs CP may include a blocking layer BX having a cylindrical shape, a charge trap layer CT formed along an inner wall of the blocking layer BX, a tunnel insulating layer TX formed along an inner wall of the charge trap layer CT, a channel layer CH formed along an inner wall of the tunnel insulating layer TX, and a core pillar CO formed in a circular pillar shape in a region surrounded by the channel layer CH. The blocking layer BX and the tunnel insulating layer TX may be formed of an oxide layer (e.g., a silicon oxide layer). The charge trap layer CT may be formed of a nitride layer. The channel layer CH may be formed of a doped silicon layer. The core pillar CO may be formed of an insulating layer or a conductive layer. The blocking layer BX, the charge trap layer CT, the tunnel insulating layer TX, the channel layer CH, and the core pillar CO, which are formed in the cell plug CP, may extend in a vertical direction (e.g., the Z direction). A capping layer for improving an electrical characteristic of select transistors may be further formed on the top of the core pillar CO.

Sub-support patterns SSP may be formed in the support holes H1 formed in the alignment key region AKA. For example, a support material layer (e.g., a conductive material) is filled in the support holes H1, thereby forming the sub-support patterns SSP.

In FIG. 3C, the sub-support patterns SSP may be formed in the support holes H1 after the cell plugs CP are formed in the cell holes CPH, and the cell plugs CP may be formed in the cell holes CPH after the sub-support patterns SSP are formed in the support holes H1. Alternatively, the cell plugs CP and the sub-support patterns SSP may be simultaneously formed.

In addition, although a case where the support holes H1 are simultaneously formed with the cell holes CPH is mainly illustrated in FIGS. 3B and 3C, various embodiments may be possible. For example, after the cell plugs CP are formed in the cell array region CA, the support holes H1 may be formed while contact plugs are formed on the top of the cell plugs CP. After that, a support material layer is filled in the support holes H1, thereby forming the sub-support patterns SSP.

Referring to FIG. 3D, a slit trench SLT may be formed, which penetrates the stack structure STK of the cell array region CA. The first material layers M1 may be exposed by the slit trench SLT. The slit trench SLT may extend in the Y direction. The cell array region CA may be divided into a plurality of memory blocks by the slit trench SLT. An anisotropic dry etching process may be performed to form the slit trench SLT at a specified position.

Trenches T1 penetrating the stack structure STK may be formed in the alignment key region AKA. The first material layers M1 may be exposed by the trenches T1. The trenches T1 may extend parallel to each other along the Y direction. The trenches T1 may be formed to be spaced apart from each other along the X direction. An anisotropic dry etching process may be performed so as to form the trenches T1 at specified positions.

The trenches T1 may be formed such that at least one sub-support patterns SSP is located between two trenches T1 adjacent to each other. For example, the trenches T1 may be formed at both sides (e.g., the X direction and the opposite direction of the X direction) of sub-support patterns SSP arranged along the X direction.

In an embodiment, the slit trench SLT and the trenches T1 may be simultaneously formed through an etching process. For example, through a one-time etching process, the slit trench SLT may be formed in the cell array region CA, and the trenches T1 may be formed in the alignment key region AKA. In another embodiment, the slit trench SLT and the trenches T1 may be formed through separate etching processes.

Referring to FIG. 3E, the first material layers M1 exposed through the slit trench SLT in the cell array region CA may be removed. An etching process for removing the first material layers M1 through the slit trench SLT may be performed. The etching process may be a wet etching process for allowing the second material layers M2 to remain and selectively removing the first material layers M1.

In addition, the first material layers M1 exposed through the trenches T1 in the alignment key region AKA may be removed. An etching process for removing the first material layers M1 through the trenches T1 may be performed. The etching process may be a wet etching process for allowing the second material layers M2 to remain and selectively removing the first material layers M1.

The etching processes of removing the first material layers M1 through the slit trench SLT and the trenches T1 may be simultaneously performed. The first material layers M1 may be selectively removed through an isotropic etching process performed through the slit trench SLT and the trenches T1.

As the first material layers M1 are removed through the trenches T1 in the alignment key region AKA, first recesses RC1 may be opened between the second material layers M2. The first recesses RC1 may correspond to positions at which the first material layers M1 on the alignment key region AKA are removed. In addition, as the first material layers M1 are removed through the slit trench SLT in the cell array region CA, second recesses RC2 may be opened between the second material layers M2. The second recesses RC2 may correspond to positions at which the first material layers M1 on the cell array region CA are removed.

The first recesses RC1 may expose portions of a sidewall of each of the sub-support patterns SSP. In addition, the second recesses RC2 may expose portions of a sidewall of each of the cell plugs CP.

Although the first material layers M1 are removed in the cell array region CA, the second material layers M2 may be supported by the cell plugs CP. For example, although the second recesses RC2 are formed in the cell array region CA, the cell plugs CP support the second material layers M2. Thus, the second material layers M2 do not collapse, or second material layers M2 in different layers are not connected to each other.

In accordance with an embodiment of the present disclosure, the second material layers M2 may be supported by the sub-support patterns SSP even when the first material layers M1 are removed even in the alignment key region AKA. For example, although the first recesses RC1 are formed in the alignment key region AKA, the sub-support patterns SSP support the second material layers M2. Thus, the second material layers M2 do not collapse, or second material layers M2 in different layers are not connected to each other (e.g., no bridge phenomenon). Accordingly, the structural stability of the semiconductor device can be improved as compared with a case where the sub-support patterns SSP are not formed in the alignment key region AKA. In addition, when at least some of the second material layers M2 collapse in a state in which the first recesses RC1 are formed, various defects such as cracks, burst, dishing, and slurry stuck may occur due to subsequent processes. However, in accordance with embodiments of the present disclosure, the occurrence of the defects is prevented, so that the yield of the semiconductor device can be improved.

Referring to FIG. 3F, third material layers M3 may be formed in regions between the second materials M2, in which the first material layers M1 are removed. That is, the third material layers M3 may be formed in the first recesses RC1 and the second recesses RC2. Since the third material layers M3 formed in the regions between the second material layers M2 are used as gate lines, the third material layers M3 may be formed of a conductive material. For example, the third materials M3 may be formed of at least one of tungsten (W), cobalt (Co), nickel (Ni), molybdenum (Mo), silicon (Si), and poly-silicon (poly-Si).

While the third material layers M3 are formed in the first and second recesses RC1 and RC2, the third material layers M3 may be formed even in the slit trench SLT and the trenches T1. For example, the third material layers M3 may be formed even on an inner wall and a bottom surface of the slit trench SLT and inner walls and bottom surfaces of the trenches T1.

Referring to FIG. 3G, the third material layers M3 formed in the slit trench SLT and the trenches T1 may be removed. For example, the third material layers M3 formed in the slit trench SLT and the trenches T1 may be removed through an anisotropic dry etching or an isotropic wet etching process on the slit trench SLT and the trenches T1. As the third material layers M3 formed on the inner wall and the bottom surface of the slit trench SLT and the inner walls and the bottom surfaces of the trenches T1 are removed, the third material layers M3 in the regions between the second material layers M2 may be insulated from each other.

Referring to FIG. 3H, fourth material layers may be formed in the trenches T1 of the alignment key region AKA. Alignment keys AK may include the fourth material layers filled in the trenches T1. Each of the fourth material layers may be an insulating layer. The alignment keys AK may be used for alignment between the substrate SST and the photomask in a subsequent process.

A slit SL may be formed in the slit trench SLT of the cell array region CA. The slit SL may include a slit material layer filled in the slit trench SLT. The slit material layer may be a single layer or a multi-layer. For example, the slit SL may include a single layer formed of an insulating layer or amorphous silicon. In another example, the slit SL may include a slit insulating layer formed along the inner wall of the slit trench SLT and a slit conductive layer surrounded by the slit insulating layer.

The alignment key AK and the slit SL may be simultaneously or sequentially formed. For example, a process of filling the trenches T1 with the fourth material layers and a process of filling the slit trench SLT with the slit material layer may be simultaneously formed. In another example, after the alignment keys AK are formed by filling the trenches T1 with the fourth material layers, the slit SL may be formed by filling the slit trench SLT with the slit material layer. In still another example, after the slit SL is formed by filling the slit trench SLT with the slit material layer, the alignment keys AK may be formed by filling the trenches T1 with the fourth material layers.

Although a case where the semiconductor device in accordance with the present disclosure is a memory device is mainly described in FIGS. 3A to 3H, the scope of the present disclosure is not limited thereto. For example, the semiconductor device may include the alignment pattern AP on the scribe lane region SLA even though the semiconductor memory device is a non-memory device, the sub-support patterns SSP and the alignment keys AK in accordance with the present disclosure may be formed in the scribe lane region SLA while the semiconductor integration process is performed in the chip region CHA.

FIGS. 4 to 7 are views illustrating structures of a semiconductor device in accordance with various embodiments of the present disclosure. FIGS. 4 to 7 are plan views illustrating layouts of sub-support patterns SSP formed in the alignment key region AKA. In FIGS. 4 to 7, descriptions of components overlapping with those shown in FIG. 2A will be simplified or omitted.

Referring to FIGS. 4 and 5, a section of each of sub-support patterns SSPa may be a rectangle. A length of the section of each of the sub-support patterns SSPa in one direction may be longer than a length of the section of each of the sub-support patterns SSPa in the other direction. For example, a section of one of the sub-support patterns SSPa may have a major axis in the X direction and a minor axis in the Y direction. In addition, a section of another of the sub-support patterns SSPa may have a major axis in the Y direction and a minor axis in the X direction. Each of the sub-support patterns SSPa may extend in a direction (e.g., the Z direction) perpendicular to the substrate SST.

Referring to FIG. 4, even when the section of each of the sub-support patterns SSPa is not a circle, at least two sub-support patterns SSPa may be located between two alignment keys adjacent to each other among alignment keys AK. For example, two sub-support patterns SSPa may be arranged in parallel to each other in the X direction between two alignment keys adjacent to each other among the alignment keys AK.

Referring to FIG. 5, each of sub-support patterns SSPa arranged along the X direction may be located between two alignment keys AK adjacent to each other. For example, the sub-support patterns SSPa arranged along the X direction may be alternately arranged with alignment keys AK arranged along the X direction. Alternatively, the alignment keys AK may be respectively located between the sub-support patterns SSPa arranged along the X direction.

The sub-support patterns SSPa may be formed by filling a support material layer (e.g., a conductive material) in support trenches each extending in the X direction (or the Y direction). Each of the support trenches may penetrate a stack structure (e.g., the stack structure STK shown in FIG. 3A) and extend in the X direction (or the Y direction). The support trenches may be arranged along the X direction (or the Y direction).

Referring to FIGS. 2A, 4, and 5 together, the number of sub-support patterns SSP1 or SSPa located between two alignment keys AK adjacent to each other may be variously formed. Various embodiments are possible in addition to the arrangements of the sub-support patterns SSP1 and SSPa shown in FIGS. 2A, 4, and 5. For example, the sub-support patterns SSP1 or SSPa may be located in various forms between the alignment keys AK as long as a direction (e.g., the Y direction) in which the alignment keys AK extend and a direction in which the sub-support patterns SSPa extend (or a direction in which the sub-support patterns SSPa or SSP1 are arranged) (e.g., the X direction) are formed perpendicular to each other.

Referring to FIGS. 4 to 6, a section of each of sub-support patterns SSPa or SSPb may be a quadrangle having round corners or an ellipse in addition to the rectangle. In addition, each of the sub-support patterns SSPa or SSPb may be formed in various shapes capable of supporting the stack structure STK between the alignment keys AK.

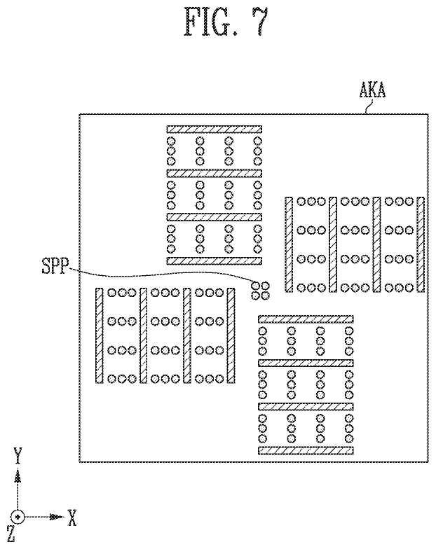

Referring to FIG. 7, additional support pillars SPP may be further formed in the alignment key region AKA, in addition to sub-support patterns. Referring to FIGS. 2A and 7 together, the support pillars SPP spaced apart from the first to fourth alignment patterns AP1 to AP4 may be located on the alignment key region AKA. For example, the support pillars SPP may be substantially formed in a central region of the alignment key region AKA. The number and positions of support pillars SPP are not limited to those shown in FIG. 7.

The support pillars SPP may have a shape similar to or different from the shape of the sub-support patterns SSP1, SSP2, SSP3, and SSP4. For example, each of the support pillars SPP may have a circular pillar shape. In another example, each of the support pillars SPP may have a circular pillar shape of which section has a large diameter, as compared with the first to fourth sub-support patterns SSP1 to SSP4. The shape of the support pillars SPP is not limited to that shown in FIG. 7.

The support pillars SPP along with the first to fourth support patterns SP1 to SP4 may support the stack structure STK. For example, when the first recesses RC1 are formed as shown in FIG. 3E, the sub-support patterns SSP and the support pillars SPP may support the stack structure STK such that the second material layers M2 of the stack structure STK do not collapse.

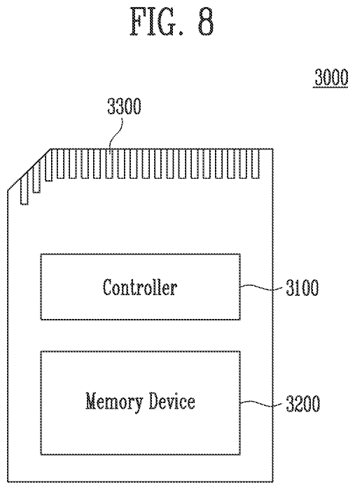

FIG. 8 is a diagram illustrating a memory card system to which the memory device of the present disclosure is applied.

Referring to FIG. 8, the memory card system 3000 includes a controller 3100, a memory device 3200, and a connector 3300.

The controller 3100 may be connected to the memory device 3200. The controller 3100 may access the memory device 3200. For example, the controller 3100 may control a program, read or ease operation, or control a background operation of the memory device 3200. The controller 3100 may provide an interface between the memory device 3200 and a host. The controller 3100 may drive firmware for controlling the memory device 3200. For example, the controller 3100 may include components such as a Random Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. The controller 3100 may communicate with the external device through at least one of various communication standards or interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe. For example, the connector 3300 may be defined by at least one of the above-described various communication standards or interfaces.

The memory device 3200 may include memory cells.

The controller 3100 and the memory device 3200 may be integrated into a single semiconductor device, to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

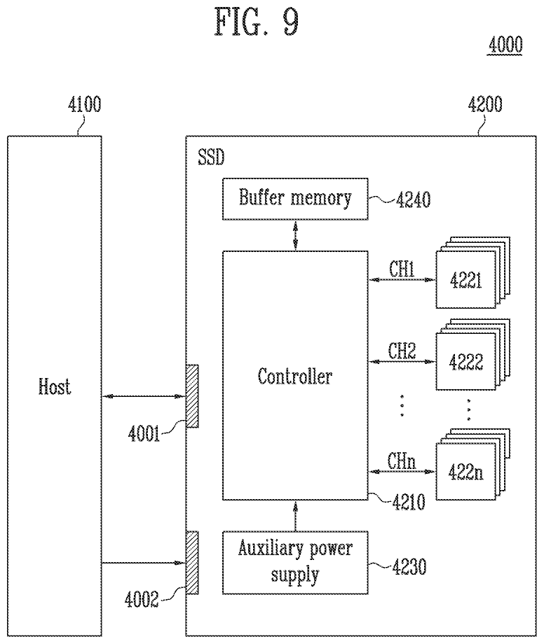

FIG. 9 is a diagram illustrating a Solid State Drive (SSD) system to which the memory device of the present disclosure is applied.

Referring to FIG. 9, the SSD system 4000 may include a host 4100 and an SSD 4200. The SSD 4200 may exchange a signal with the host 4100 through a signal connector 4001, and receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. The signal may be a signal based on an interface between the host 4100 and the SSD 4200. For example, the signal may be a signal defined by at least one of communication interfaces or standards such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power input from the host 4100 and charge the power. When the supply of power from the host 4100 is not smooth, the auxiliary power supply 4230 may provide power to the SSD 4200. The auxiliary power supply 4230 may be located in the SSD 4200, or be located at the outside of the SSD 4200. For example, the auxiliary power supply 4230 may be located on a main board, and provide auxiliary power to the SSD 4200.

The buffer memory 4240 may operate as a buffer memory of the SSD 4200. For example, the buffer memory 4240 may temporarily store data received from the host 4100 or data received from the plurality of memory devices 4221 to 422n, or temporarily store meta data (e.g., a mapping table) of the memory devices 4221 to 422n. The buffer memory 4240 may include volatile memories such as a DRAM, an SDRAM, a DDR SDRAM, an LPDDR SDRAM, and a GRAM or nonvolatile memories such as a FRAM, a ReRAM, an STT-MRAM, and a PRAM.

In accordance with embodiments of the present disclosure, the structural stability of a region in which an alignment pattern is formed can be improved, thereby reducing occurrence of defects in the semiconductor device.

While the present disclosure has been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all operations may be selectively performed or part of the operations may be omitted. In each embodiment, the operations are not necessarily performed in accordance with the described order and may be rearranged. The embodiments disclosed in this specification and drawings are only examples to facilitate an understanding of the present disclosure, and the disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to describe the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein. Furthermore, the embodiments may be combined to form additional embodiments.

What is claimed is:

1. A semiconductor device comprising:
a lower structure including a chip region and a scribe lane region surrounding the chip region;
a first alignment pattern including first alignment keys extending parallel to each other along a first direction on the scribe lane region; and
a support pattern including first sub-support patterns arranged along a second direction intersecting the first direction between the first alignment keys.

2. The semiconductor device of claim 1, wherein each of the first sub-support patterns has a circular pillar shape extending vertically to the lower structure.

3. The semiconductor device of claim 1, wherein each of the first sub-support patterns has a plane having a major axis in the second direction and a minor axis in the first direction, and extends vertically to the lower structure.

4. The semiconductor device of claim 1, wherein at least two of the first sub-support patterns are located between two alignment keys adjacent to each other among the first alignment keys.

5. The semiconductor device of claim 1, wherein each of the first sub-support patterns is located between two alignment keys adjacent to each other among the first alignment keys.

6. The semiconductor device of claim 1, wherein each of the first alignment keys and each of the first sub-support patterns are spaced apart from each other.

7. The semiconductor device of claim 1, further comprising second sub-support patterns arranged along the second direction from the first direction with respect to the first sub-support pattern.

8. The semiconductor device of claim 1, wherein an angle between the first direction and the second direction is 90 degrees.

9. The semiconductor device of claim 1, further comprising a stack structure including a stack structure including conductive layers and interlayer insulating layers, which are alternately stacked on the scribe lane region,
wherein each of the first alignment keys and the first sub-support patterns penetrates the stack structure.

10. The semiconductor device of claim 1, wherein each of the first alignment keys includes an insulating layer.

11. The semiconductor device of claim 1, wherein each of the sub-support patterns is made of a conductive material.

12. The semiconductor device of claim 1, further comprising:
a second alignment pattern including second alignment keys extending parallel to each other along the second direction on the scribe lane region; and
a second support pattern including second sub-support patterns arranged along the first direction between the second alignment keys.

13. The semiconductor device of claim 12, further comprising a support pillar spaced apart from the first alignment pattern and the second alignment pattern.

14. A method of manufacturing a semiconductor device, the method comprising:
forming a stack structure by alternately stacking first material layers and second material layers on a lower structure including a chip region and a scribe lane region surrounding the chip region;
forming sub-support patterns penetrating the stack structure of the scribe lane region, the sub-support patterns being arranged along a first direction;
forming trenches penetrating the stack structure of the scribe lane region, the trenches extending parallel to each other along a second direction intersecting the first direction;
forming recesses by removing the first material layers exposed through the trenches;
forming third material layers in the recesses through the trenches; and
forming an alignment pattern by filling a fourth material layer in the trenches.

15. The method of claim 14, wherein the forming of the sub-support patterns includes:
forming support holes arranged along the first direction; and
forming the sub-support patterns by filling a support material layer in the support holes.

16. The method of claim 14, wherein the forming of the sub-support pattern includes:
forming support trenches each extending in the first direction; and
forming the sub-support patterns by filling a support material layer in the support trenches.

17. The method of claim 14, wherein the forming of the sub-support pattern includes forming first sub-support patterns arranged along the first direction and second sub-support patterns arranged along the first direction from the second direction with respect to the first sub-support patterns.

18. The method of claim 14, wherein, in the forming of the trenches, the trenches are formed such that at least one of the sub-support patterns is located between two trenches adjacent to each other among the trenches.

19. The method of claim 14, wherein the recesses expose the sub-support patterns.

20. The method of claim 14, wherein, in the forming of the recesses, the stack structure is supported by the sub-support patterns.
